(19) United States
(12) Patent Application Publication
(10) Pub. No.: US 2018/0320859 A1
(43) Pub. Date: Nov. 8, 2018

(54) ELECTRONICS CASE WITH LIGHT-REFLECTIVE ELEMENTS

(71) Applicant: CASE-MATE, INC., Atlanta, GA (US)

(72) Inventors: Nitin Koshy PHILIP, Sandy Springs, GA (US); Saumil Chetan MODY, Atlanta, GA (US)

(73) Assignee: CASE-MATE, INC., Atlanta, GA (US)

(21) Appl. No.: 15/971,182

(22) Filed: May 4, 2018

Related U.S. Application Data
(60) Provisional application No. 62/501,205, filed on May 4, 2017.

(51) Int. Cl. F21V 13/08; F21V 7/26; H05K 5/02; F21V 9/32; F21K 9/64; F21L 4/04; H05K 5/06

(52) U.S. Cl. CPC F21V 13/08; F21V 7/26; H05K 5/02; G02B 1/00; F21K 9/64; F21L 4/04; H05K 5/069; F21V 9/32

(57) ABSTRACT

A protective and ornamental case for handheld electronic devices, the case comprising one or more light-reflective and/or luminescent elements, for example arranged in a pattern. The luminescent elements are generally attached or formed in a back panel of the case. In example embodiments, the case further incorporates one or more illumination elements or light sources, a battery or other onboard power source for the illumination elements, and/or one or more light pathways for transmission of light from the illumination elements to the reflective or luminescent elements.

### CROSS-REFERENCE TO RELATED APPLICATION

This application claims the benefit of U.S. Provisional Patent Application Ser. No. 62/501,205 filed May 4, 2017, the entirety of which is hereby incorporated herein by reference for all purposes.

### TECHNICAL FIELD

The present invention relates generally to the field of protective and ornamental cases for handheld electronic devices, and more particularly to a case incorporating light-reflective or luminescent elements.

### BACKGROUND

Cases are commonly utilized in connection with smart phones, tablet computers and other electronic devices, to protect the electronic device from damage and/or for ornamentation and style. Continuing improvements in the field are sought. It is to the provision of cases for electronic devices meeting these and other needs that the present invention is primarily directed.

### SUMMARY

In example embodiments, the present invention provides protective and ornamental cases for handheld electronic devices, and more particularly such cases incorporating one or more light-reflective and/or luminescent elements, for example arranged in a pattern. In example embodiments, the case further incorporates one or more illumination elements or light sources, a battery or other onboard power source for the illumination elements, and/or one or more light pathways for transmission of light from the illumination elements to the reflective or luminescent elements.

In one aspect, the present invention relates to an electronic device case including a plurality of reflective, luminescent or diffusing elements, and at least one light source configured to transmit or reflect light to the plurality of reflective, luminescent or diffusing elements.

In another aspect, the invention relates to an electronic device case including an outer shell covering a portion of the back of the electronic device, a plurality of luminescent elements and at least one light source. The outer shell has a back panel that defines a cavity. The plurality of luminescent elements are positioned on the back panel of the outer shell. The at least one light source is configured to impart light into the cavity and onto the luminescent elements. The case also includes a light-transmissive panel at least partially overlying the cavity in the back panel of the outer shell and covering the plurality of luminescent elements.

In still another aspect, the invention relates to an electronic device case comprising an outer shell, a plurality of reflective elements, and at least one light source. The outer shell has a back panel, a light-transmissive panel and a plug that together form a hermetically sealed liquid enclosure cavity. The plurality of reflective elements and a transparent or translucent liquid are positioned within the sealed liquid enclosure cavity. The at least one light source is configured to impart light onto the reflective elements suspended in the liquid.

In still another aspect, the invention relates to an electronic device case comprising a plurality of reflective or luminescent elements, wherein the reflective or luminescent elements are arranged in a pattern on a surface of the case, and wherein the reflective or luminescent elements comprise a material with a refractive index of at least 1.49.

These and other aspects, features and advantages of the invention will be understood with reference to the drawing figures and detailed description herein, and will be realized by means of the various elements and combinations particularly pointed out in the appended claims. It is to be understood that both the foregoing general description and the following brief description of the drawings and detailed description of example embodiments are explanatory of example embodiments of the invention, and are not restrictive of the invention, as claimed.

### BRIEF DESCRIPTION OF THE DRAWINGS

FIG. 1 is a perspective view of a case for an electronic device according to an example embodiment of the present invention, shown in an assembled configuration.

FIG. 2 is a perspective exploded view of the case of FIG. 1.

FIG. 3 is detailed perspective view of a portion of a back panel of the case of FIG. 1.

FIG. 4 is a detailed perspective view of the battery compartment and internal electronic and control components of the case of FIG. 1.

FIG. 5 is a detailed perspective view of the battery compartment cover for the case of FIG. 1.

FIG. 6A is a bottom cross sectional view of the case of FIG. 1.

FIG. 6B is a detailed cross sectional view of the bottom of the case of FIG. 6A.

FIG. 7A is a rear panel view of the case of FIG. 1, in a non-illumination mode.

FIG. 7B shows a rear panel view of the case of FIG. 1, in an illumination mode.

FIG. 8 is a top cross-sectional view of the case of FIG. 1.

FIG. 9 is a side cross-sectional view of the case of FIG. 1.

FIG. 10A is a rear panel view a case for an electronic device according to an example embodiment of the present invention, in a non-illumination mode.

FIG. 10B is a rear panel view of the case of FIG. 4B, in an illumination mode.

FIG. 11 is a back view of a case for an electronic device according to another example embodiment of the invention.

### DETAILED DESCRIPTION OF EXAMPLE EMBODIMENTS

The present invention may be understood more readily by reference to the following detailed description of example embodiments taken in connection with the accompanying drawing figures, which form a part of this disclosure. It is to be understood that this invention is not limited to the specific devices, methods, conditions or parameters described and/or shown herein, and that the terminology used herein is for the purpose of describing particular embodiments by way of example only and is not intended to be limiting of the claimed invention. Any and all patents and other publications identified in this specification are incorporated by reference as though fully set forth herein.

Also, as used in the specification including the appended claims, the singular forms “a,” “an,” and “the” include the plural, and reference to a particular numerical value includes at least that particular value, unless the context clearly dictates otherwise. Ranges may be expressed herein as from “about” or “approximately” one particular value and/or to “about” or “approximately” another particular value. When such a range is expressed, another embodiment includes from the one particular value and/or to the other particular value. Similarly, when values are expressed as approximations, by use of the antecedent “about,” it will be understood that the particular value forms another embodiment.

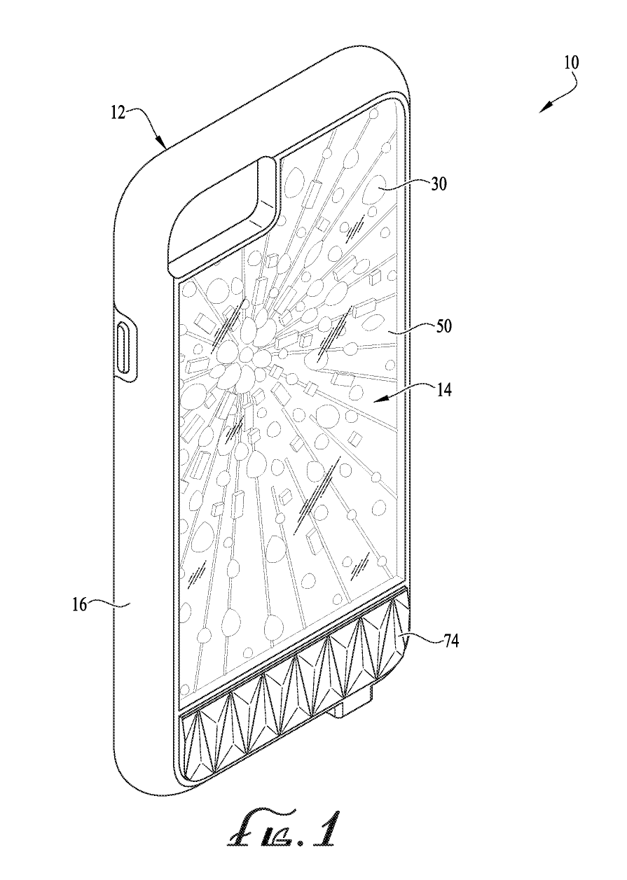

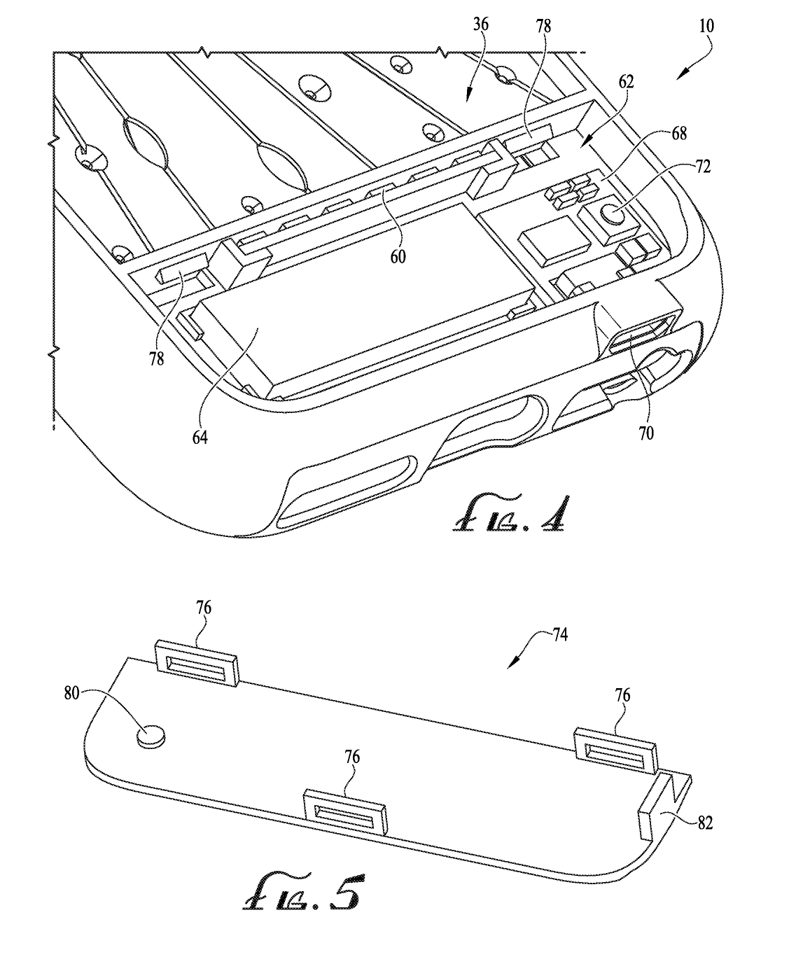

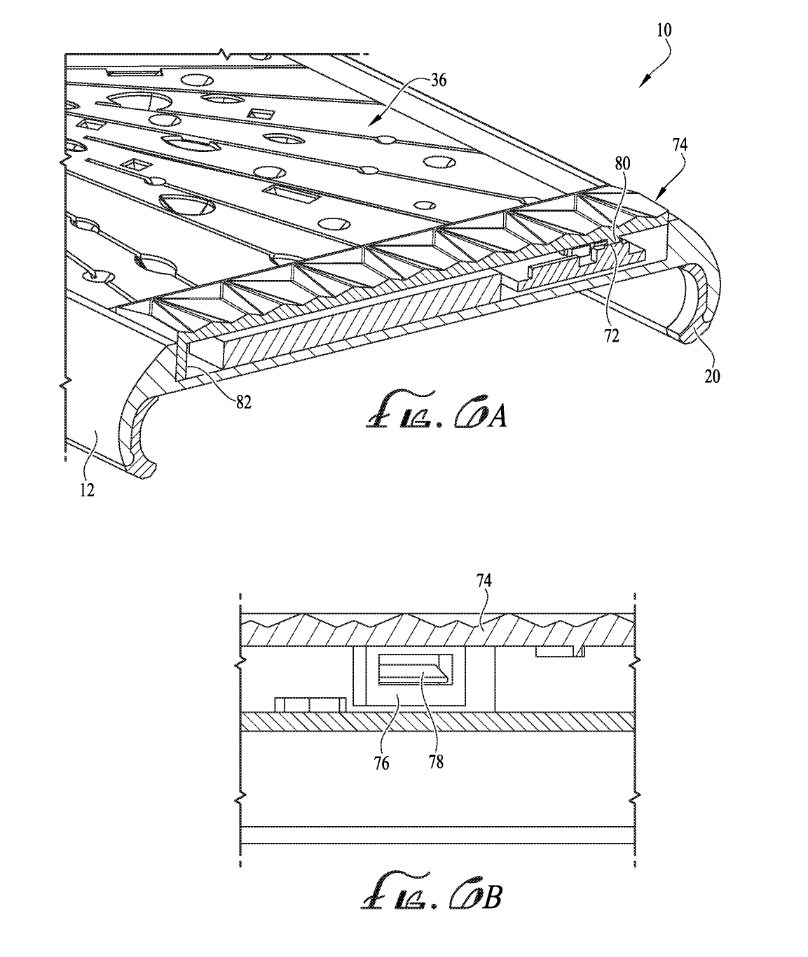

With reference now to the drawing figures, wherein like reference numbers represent corresponding parts throughout the several views, FIGS. 1-9 show a case 10 for an electronic device D according to an example embodiment of the invention. The case 10 defines a space or housing for receiving an electronic device D such as a smart phone or tablet computer. The case 10 generally comprises a shell 12 including a back panel 14 which incorporates one or more light-reflective or luminescent elements 30. In example embodiments, a plurality of reflective or luminescent elements 30 having differing sizes and/or shapes are provided, arranged in one or more patterns, for example a starburst pattern, on the back panel 14.

The electronic device case 10 generally comprises a shell 12 having a back or base panel 14 and at least one peripheral sidewall or frame 16. In the depicted embodiment, the base or back panel component 14 comprises a generally rectangular planar back with rounded corners, configured to generally match the external geometry of a specified model of smart phone device D. In alternate embodiments, the shape and size of the case are configured to generally match the external geometry of other electronic devices, such as tablet computers, smart phones, cell phones, MP3 players, and other portable music and/or video players, electronic readers, handheld game devices, and the like. The back wall 14 optionally includes one or more openings or cutouts for alignment with a camera, flash unit, controls, and/or other features of the electronic device for which the case 10 is configured for use. In example forms, the case 10 is formed of polycarbonate or other hard plastic, metal, composite, polymeric, ceramic, and/or other material(s) of construction. The shell 12 is generally configured to substantially cover the back of the electronic device D.

The case 10 further comprises one or more light-reflective or luminescent elements 30, such as sparkling multi-faceted crystals or other decorative elements. In the depicted embodiment, the luminescent elements 30 are positioned on the back panel 14 of the case shell 12. In other embodiments, the luminescent elements 30 can be positioned elsewhere on the case 10. As used herein, the terms light-reflective and luminescent include materials or objects that reflect, transmit, or refract light in a visually perceptible manner and/or to a differing extent than surrounding materials or objects. In example embodiments, the luminescent elements 30 are formed from materials such as acrylic, polystyrene, or natural resin. Example acrylics include polymethyl methacrylate. The luminescent elements 30 include one or more facets 31 configured to cast and reflect light. The luminescent elements 30 are configured to cast and reflect ambient light. In other embodiments, the case 10 includes a light source 60 discussed in further detail below. In other embodiments, the luminescent elements 30 can be formed, at least in part, from other materials that are light-reflective such as reflective microfibers such as mylar and foylon or reflective metals such as aluminum, silver, or gold. In other embodiments, the luminescent elements 30 can be formed from multiple light-reflective materials, for example a multi-faceted crystal with a backing formed from a reflective metal.

In other embodiments, the case 10 includes luminescent elements 30 that a light-refractive. The light-refractive luminescent elements are formed from a material with high refractive index. Example materials with a high refractive index include silicon, cubic zirconia, glass, polycarbonates and acrylics. Example glass materials include lead glass or crystal. The luminescent elements 30 can be formed entirely from a material with a high refractive index. In other embodiments, a coating or film comprising a material with a high refractive index is applied to an outer surface of the luminescent elements 30. High refractive index materials generally have a refractive index (n) of above about 1.45. Preferably, the luminescent elements 30 comprise a material with a refractive index of between about 1.49 and about 2.18. In other embodiments, the luminescent elements 30 comprise a material with a refractive index of between about 1.7 and about 2.18. In example embodiments, the high refractive index material is coupled with a bright, neon or fluorescent color to give the material a glow appearance. In example embodiments, a bright or neon pigment is added to the high refractive index material. In other embodiments, a bright or neon colored material is applied over or under the high refractive index material. The combination of the high refractive index material with the fluorescent color helps the luminescent element release more visible light.

In the depicted embodiments, the back panel 14 comprises the back wall portion of the outer shell 12. In example embodiments, the back panel 14 may be transparent or translucent such that the back of the device D and any logos or markings thereon will be visible. Alternatively the back panel 14 can be opaque or solid. In example embodiments, the luminescent elements 30 are attached to the back panel 14 of the case shell 12. The luminescent elements 30 can be fastened to the back panel 14 using attachment means such as an adhesive or molding technique. As seen best with reference to FIG. 3, the exterior face of the back panel 14 can have one or more recesses or cavities or cutouts 34 formed therein, each configured to have a size and shape generally corresponding to the size and shape of a reflective or luminescent element 30 to be received therein. The surfaces of these recesses or cavities 34 may have a light diffusing texture or other surface treatment applied. Surface treatments can include a mirror finish or reflective backing to provide improved light reflection.

In the depicted embodiment, the back panel 14 includes a recess or cavity 36 with a raised peripheral edge 38. The luminescent elements 30 are attached to the back panel 14 within the cavity 36. In embodiments where the back panel 14 includes individual cavities 34 for the luminescent elements 30, those cavities 34 are formed within the larger cavity 36 in the back panel. In example embodiments, the luminescent elements 30 are positioned such that they do not extend beyond the raised peripheral edge 38 of the cavity 36. In the depicted embodiment, a light-transmissive panel 50 is applied over the cavity 36 in the back panel 14 and over the reflective or luminescent elements 30. In example embodiments, the light-transmissive panel 50 is transparent or at least partially transparent, and may be tinted or colored, or in alternate embodiments may be frosted or translucent. In example embodiments, the light-transmissive panel 50 comprises an epoxy material, for example applied as a liquid over the decorative elements 30 and cured to encapsulate them. The light-transmissive panel 50 encapsulates and secures the reflective or luminescent elements 30 on the back panel 50. The light-transmissive panel 50 is configured in size and shape to fit within the cavity 36 defined in the back of the outer shell 12 and to overlie the back panel 14. In example embodiments, the light-transmissive panel 50 is positioned such that the panel and the raised peripheral edge 38 are flush.

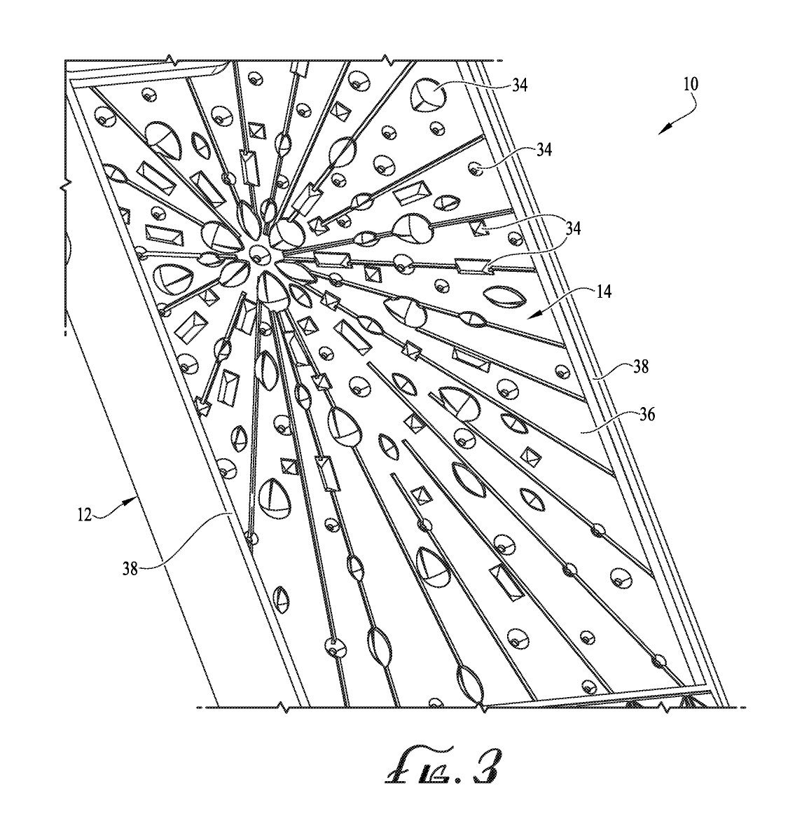

The case 10 can further comprise one or more light sources 60. The light source 60 is generally positioned to illuminate the luminescent elements 30. The light source 60 can be formed from devices such as a light-emitting diode (LED) strip with a plurality of surface-mount device (SMD) LEDs. FIGS. 4-6 shows further details of the light sources 60, and associated power and control components. The case 10 generally includes a compartment 62 formed in the outer shell 12. The compartment 62 houses the light source 60, a power source 64 for powering the light source, an integrated circuit 68 or other controller, and a charging mechanism 70. In the depicted embodiment, the light source 60 is positioned to direct light up into the cavity 36 containing the luminescent elements 30. In other embodiments, the light source 60 can be positioned at or in other parts of the case. For example, the light source 60 can include a string or pipe of light elements surrounding the cavity 38. The power source 64 can comprise a battery such as a lithium ion battery. In preferred embodiments, the power source 64 is rechargeable. In other embodiments, the power source 64 can be disposable. In example embodiments, the integrated circuit 68 includes a user input 72 such as a button or switch for user input to actuate the light source 60. Actuation of the switch 72 can be used to turn the light source 60 on and off, cycle light colors of the light source, adjust intensity of the light source, or otherwise change lighting effects. In the depicted embodiment, the power source 64 is recharged using a USB port 70 or other coupling for charging the battery. In other embodiments, other charging mechanisms 70 can be used including solar power. In the depicted embodiment, the compartment 62 is located below the cavity 36 in the back panel 14, but in alternate embodiments may be located elsewhere in or on the case 10. In other embodiments, the case 10 does not include a light source.

A battery door or cover 74 is mounted over a compartment 62 formed in the outer shell 12. In example embodiments, the battery door or cover 74 is detachably or repositionably mounted to allow access to the compartment 62. In other embodiments, the battery door or cover 74 is permanently attached over the compartment 62. In the depicted embodiment, the battery door or cover 74 includes retaining clips 76 for engagement with corresponding bosses 78 on the outer shell 12 around the compartment 62 to secure the cover over the compartment. A raised projection or boss 80 on the interior face of the battery door or cover 74 is positioned to interact with the switch 72 to allow the user to actuate and control the light source 60 by pressing on one side of the outer surface of the battery door. In the depicted embodiment, the outer surface of the battery door does not include an obvious button or switch. In other embodiments, the case 10 can include a button or switch on the exterior of the case for user input. A positioning flange 82 is optionally provided on the other side of the interior face of the battery door or cover 74, opposite the boss 80, to restrict movement of the battery door on that side. The exterior side of the battery door or cover 62 optionally comprises a decorative pattern 84.

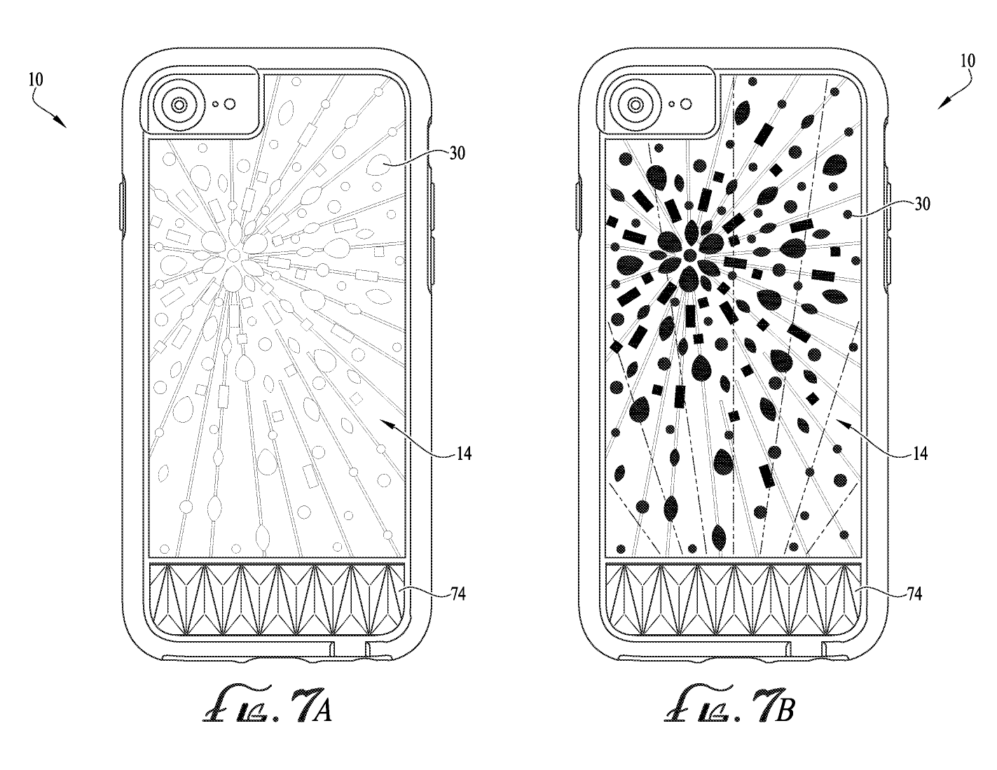

As shown in FIG. 7, light from the light source 60 is transmitted and/or reflected over and through the array of reflective or luminescent elements 30 to generate an illuminated appearance. The light provided may be useful for finding objects (including the case itself), for signaling or identification, for ornamentation, and/or various other purposes. The light sources 60 may optionally be operable in multiple modes, for example white light, light of different colors, different intensities of light, blinking, and/or sequences or patterns of lighting, etc. FIG. 7A shows the case in a non-illumination (lights off) mode, and FIG. 7B shows the case in an illumination (lights on) mode. The reflective or luminescent elements 30 preferably have a different refractive index than the light-transmissive panel 50, in order to generate a differentially illuminated appearance, for example with the reflective or luminescent elements 30 appearing to glow within the field of the light-transmissive panel 50, forming an illuminated pattern. In the depicted embodiment, the luminescent elements 30 are arranged in a sparkling starburst pattern. In alternate embodiments, the pattern of decorative elements 30 comprises one or more patterns such as for example, a starburst pattern, a pattern of lines, a pattern of arcs or curves, a pattern of individual elements, a spiral pattern, a circular pattern, and/or other defined or random pattern elements, as well as combinations thereof. In other embodiments, the luminescent elements 30 are arranged to form letters, words, or characters. The luminescent elements 80 optionally include a mirror finish or reflective backing to provide improved light reflection.

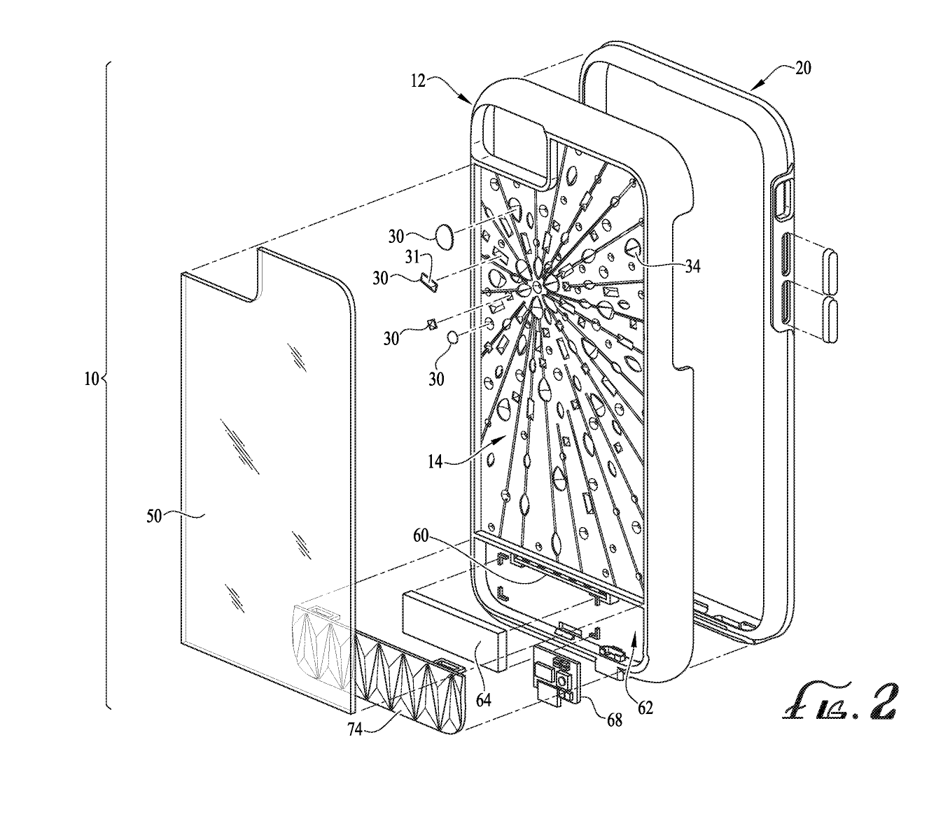

In example forms, the case 10 comprises a two-part case with an inner layer or sleeve 20 within the outer layer or shell 12 that can removably engage with respect to each other, as shown in FIG. 2. The inner layer 20 preferably comprises a flexible form-fit bumper that protects the electronic device without significantly covering the front and back of the device D. This inner layer bumper 20 is preferably constructed of soft and/or flexible material, for example plastic or rubber and more preferably thermoplastic polyurethane, and provides a degree of resilience or compressibility to protect the electronic device from impacts. Preferably, the inner layer bumper 20 has a continuous unitary construction with four sides forming a generally rectangular frame shape. The inner layer bumper 20 also is depicted to have an open center between the four sides. The bumper 20 also preferably has a face surface 22 and a collar 26. The collar 26 extends generally perpendicularly from the rear surface of the face 22. The collar 26 can have a straight, slightly concave or slightly convex disposition. The inner layer bumper 20 can have one or more raised protrusions 24 positioned along the outer surface of the collar 20. Preferably, more than one raised protrusions 24 are included at multiple positions along the outer surface of the collar 20. The inner layer bumper 20 can also have one or more apertures 26 extending through the collar 20 and/or the face 22. The one or more apertures 26 are designed to align with and provide access to input/output jacks or connection ports on a particular electronic device D.

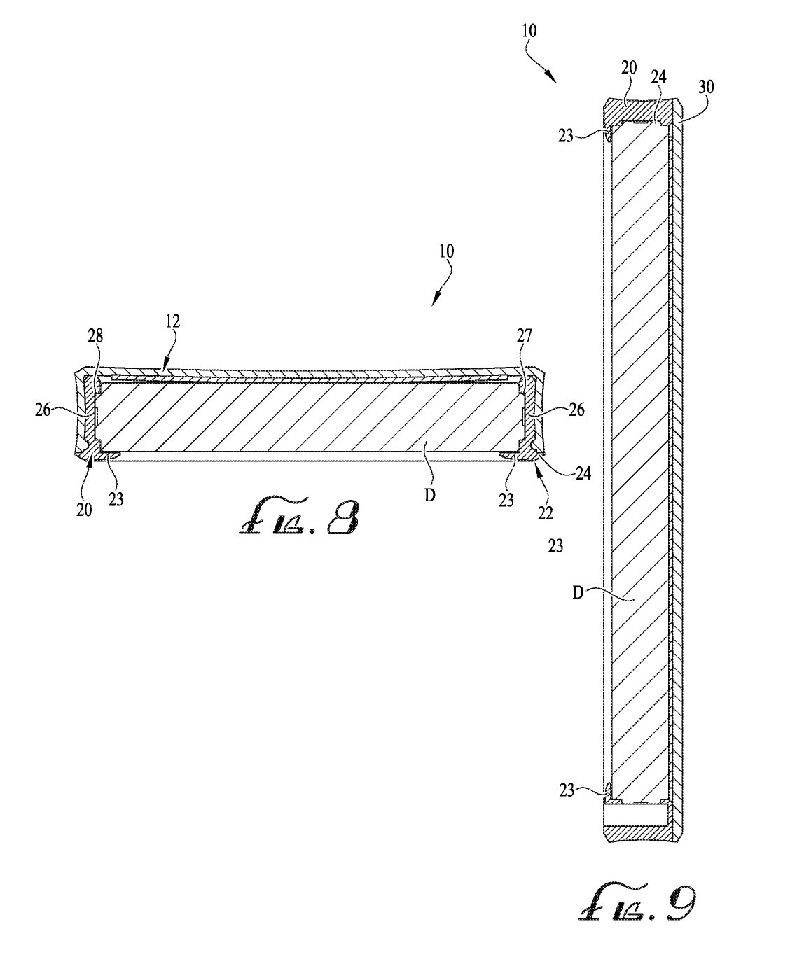

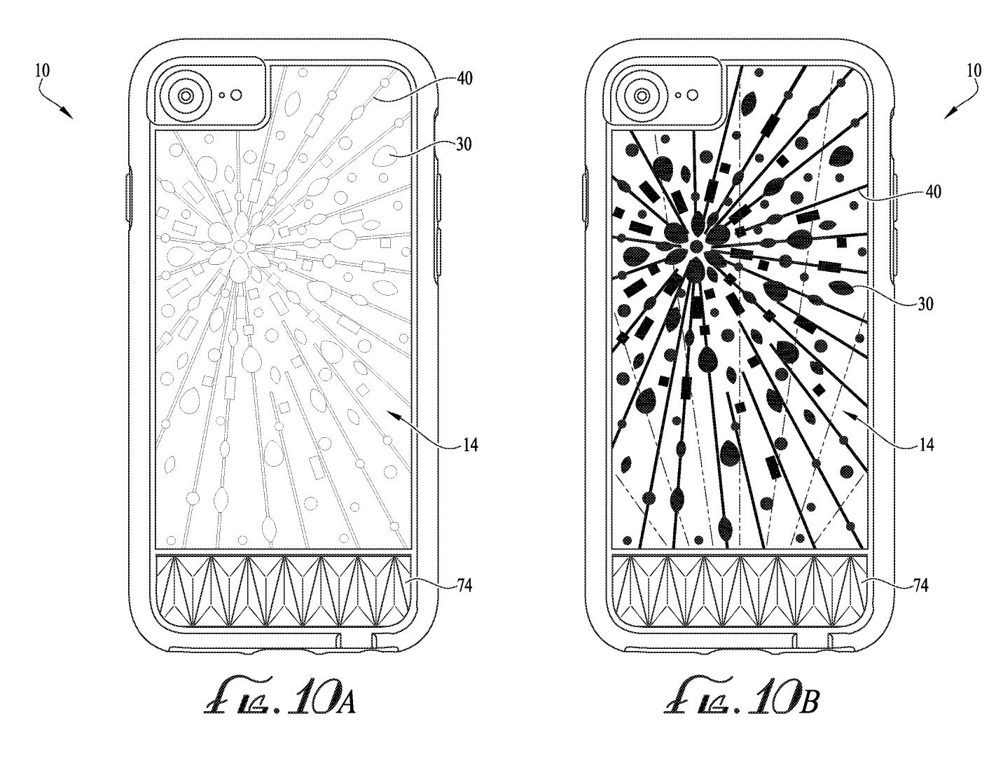

As shown in FIGS. 8 and 9, the inner layer bumper 20 can have a subtle undercut geometry to receive the electronic device D and to engage with the outer layer shell 12. The undercut geometry can include one or more inwardly-directed lips 23 forming part of the face 22. These one or more lips 23 can extend inwardly from each of the four sides of the face 22 forming a continuous annular lip. These one or more lips 23 engage the outer edges of the front surface of the electronic device D. The collar 26 can also include one or more ridge grips 28 extending inwardly from the distal end of the collar opposite the connection with the face 22. The inner layer bumper 20 can include one of these ridge grips 28 positioned along one edge or alternatively, it can include more than one of these ridge grips 28 positioned on multiple edges. The combination of the lip 23 and the one or more ridge grips 28 provides a receiver within which the electronic device D can be removably inserted and secured to retain the bumper in place on the electronic device. U.S. Pat. No. 8,695,798 is hereby incorporated herein by reference, and shows additional details of an outer shell and inner bumper configuration suited for adaptation in connection with example embodiments of the present invention. It will be understood, however, that various other case configurations may also be adapted for use in connection with example embodiments of the present invention.

In use, the user installs the case 10 onto a mobile phone, tablet computer or other handheld electronic device D. If necessary, the battery 64 is charged by connection of a charging cable or otherwise. The light source 60 is actuated and controlled by pressing on the battery compartment cover 74 to operate the switch 72. Light from the light source 60 illuminates the reflective elements 30 to form one or more illuminated patterns or displays. The user can operate the switch 72 or an additional input mechanism to change the light mode of the lighting source 60 or turn off the light source.

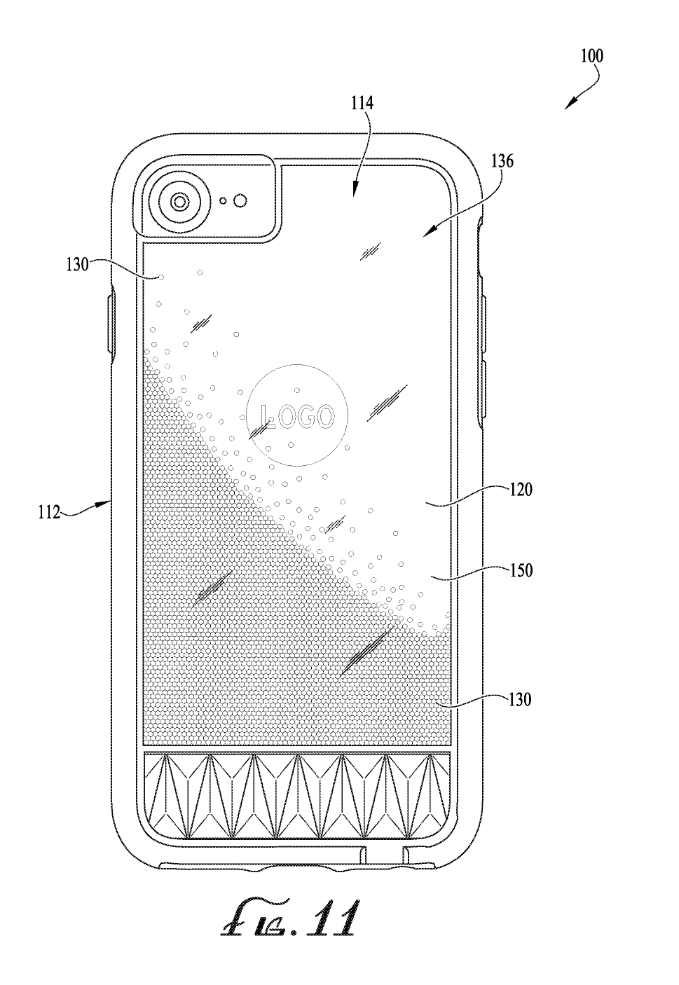

In additional embodiments, the luminescent elements 30 can include one or more reflective lines 40. As shown in FIG. 10, the reflective lines 40 can be applied to the back panel 14 of the case. In example embodiments, the lines 40 are arranged to form a pattern, for example forming rays of a starburst pattern. In depicted embodiments, the reflective lines 40 extend between or through the positions of the reflective or luminescent elements 30. In alternate embodiments, the pattern of the lines 40 comprises one or more patterns such as for example a pattern of lines, a pattern of arcs or curves, a pattern of individual elements, a spiral pattern, a circular pattern, and/or other defined or random pattern elements, as well as combinations thereof. In other embodiments, lines 40 are arranged to form letters, words, or characters. In example embodiments, the lines 40 are painted onto the back panel 14 of the case 10. The painted lines can comprise a metallic paint or non-conductive vacuum metallization material (NCVM). In other embodiments, the lines 40 are formed from reflective material molded into the back panel 14 of the case 40. In still other embodiments, the lines 40 are formed from the light source 60, for example strands of LED lights are attached to or embedded in the back panel 14 to form the desired pattern.

FIG. 11 shows a case 100 according to another example embodiment of the invention. The case 100 includes a light source and associated elements contained in a compartment as in the previous embodiment. The case 100 of the depicted embodiment comprises a “waterfall” panel 150 forming a hermetically sealed liquid enclosure 136 over the back panel 114 of the outer shell 112. In this embodiment, the outer shell 112 includes a back panel 114, a light-transmissive panel 150, and a plug that together form a hermetically sealed liquid enclosure cavity 136. A liquid 120, such as for example mineral oil or water is introduced into the cavity 136 through the hole covered by the plug. The liquid 120 is generally translucent or opaque. The fill hole is closed or sealed, for example by insertion of a soft plastic stopper. In example embodiments, the stopper is formed from a thermoplastic elastomer or other soft plastic material suitable for compression fit and sealing within the fill hole, and has a smaller inner portion and a flared or expanded outer portion.

In the depicted embodiment, the luminescent element 130 is formed from reflective decorative elements such as metallic or metalized glitter, beads, or particles floating in a liquid within the enclosure. A plurality of reflective decorative elements 130 are contained within the sealed liquid enclosure cavity 136 such that they can move in the liquid 120. Light from at least one light source(s) such as an LED light source is transmitted and/or reflected through the liquid enclosure and reflects off of the reflective decorative elements to generate a moving “waterfall” pattern of light and motion.

While the invention has been described with reference to example embodiments, it will be understood by those skilled in the art that a variety of modifications, additions and deletions are within the scope of the invention, as defined by the following claims.

What is claimed is:

1. An electronic device case comprising a plurality of reflective or luminescent elements, and at least one light source configured to transmit or reflect light to the plurality of reflective or luminescent elements.

2. The electronic device case of claim 1, wherein the plurality of reflective or luminescent elements are formed from a resin.

3. The electronic device case of claim 1, wherein the plurality of reflective or luminescent elements each include at least one facet.

4. The electronic device case of claim 1, wherein the plurality of reflective or luminescent elements are arranged in a defined pattern.

5. The electronic device case of claim 4, wherein the defined pattern is selected from a starburst pattern, a pattern of lines, a pattern of arcs or curves, a pattern of individual elements, a spiral pattern, a circular pattern, and/or other defined or random pattern elements, and combinations thereof.

6. The electronic device case of claim 1, further comprising a plurality of reflective shapes such as lines applied in proximity to the plurality of reflective or luminescent elements.

7. The electronic device case of claim 6, wherein the plurality of reflective shapes are formed from metallic paint.

8. The electronic device case of claim 6, wherein the plurality of reflective shapes are formed from a non-conductive vacuum metallization material.

9. A case for an electronic device comprising:
an outer shell having a back panel comprising a cavity, the back panel covering a portion of the back of the electronic device;
a plurality of luminescent elements positioned on the back panel of the outer shell;
at least one light source configured to impart light into the cavity and onto the luminescent elements;
a light-transmissive panel at least partially overlying the cavity in the back panel of the outer shell and covering the plurality of luminescent elements.

10. The case for an electronic device of claim 9, wherein the back panel comprises a plurality of small cutouts wherein each luminescent element is positioned within a corresponding cutout in the back panel.

11. The case for an electronic device of claim 9, wherein the luminescent elements comprise a plurality of crystals.

12. The case for an electronic device of claim 9, wherein the light source comprises a plurality of light emitting diodes.

13. The case for an electronic device of claim 9, wherein the light source includes a power source independent of the electronic device.

14. The case for an electronic device of claim 13, wherein the power source is rechargeable.

15. The case for an electronic device of claim 9, wherein the light source further comprises a user actuated switch for activating the light source.

16. The case for an electronic device of claim 15, wherein the user actuated switch is positioned on a cover configured to cover the light source.

17. The case for an electronic device of claim 9, wherein the light source includes a plurality of light modes.

18. The case for an electronic device of claim 9, further comprising a plurality of reflective shapes such as lines applied in proximity to the plurality of reflective or luminescent elements.

19. The case for an electronic device of claim 9, wherein the plurality of reflective or luminescent elements are arranged in a defined pattern.

20. An electronic device case comprising:
an outer shell having a back panel, a light-transmissive panel and a plug that together form a hermetically sealed liquid enclosure cavity;
a plurality of reflective elements and a transparent or translucent liquid positioned within the sealed liquid enclosure cavity; and
at least one light source configured to impart light onto the reflective elements.

21. An electronic device case comprising a plurality of reflective or luminescent elements, wherein the reflective or luminescent elements are arranged in a pattern on a surface of the case, and wherein the reflective or luminescent elements comprise a material with a refractive index of at least 1.49.
